(19) United States
(12) Patent Application Publication
(10) Pub. No.: US 2006/0192471 A1
(43) Pub. Date: Aug. 31, 2006

(54) Organic electroluminescent device

(75) Inventors: Hirotada Inoue, Kobe-city (JP); Noriyuki Matsusue, Ibaraki-city (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/363,169

(22) Filed: Feb. 28, 2006

(30) Foreign Application Priority Data
Feb. 28, 2005 (JP) 2005-054147
Feb. 28, 2005 (JP) 2005-054148

(51) Int. Cl. H01L 51/52; H05B 33/12

(52) U.S. Cl. 313/113; 313/112; 313/506; 257/98; 428/917; 257/E51.021

(57) ABSTRACT

An electroluminescent device comprising: a luminous layer provided between a first electrode and a second electrode; and a reflective layer provided on the first electrode side for reflecting light emitted from the luminous layer and emitting the light from said second electrode side; wherein an optical distance L₁ between a light-emitting position of the luminous layer and the reflective layer is determined so as to allow the light with wavelength λ, which is center wavelength of the emitted light to be taken out, to increase in intensity as a result of interference, and wherein an optical distance L₂ between a reflective interface at the device end portion on the second electrode side and the reflective layer is determined so as to allow the light with wavelength λ to decrease in intensity as a result of interference.

### BACKGROUND OF THE INVENTION

1. Field of the Invention

The present invention relates to an organic electroluminescent device, and in particular, to an organic electroluminescent device comprising a luminous layer provided between a first electrode and a second electrode, and a reflective layer provided on the first electrode side for reflecting light emitted from the luminous layer and emitting the light from the second electrode side.

2. Description of the Related Art

Organic electroluminescent devices (organic EL devices) generally have a structure where an organic layer that includes a luminous layer having a thickness of approximately several tens of nm to several hundreds of nm is sandwiched between an electrode having reflecting properties and an electrode having translucence. In such organic EL devices, light that has been emitted from the luminous layer interferes in the device structure before being emitted to the outside. Conventionally, it has been attempted to use such interference to increase the luminous efficiency.

Japanese Unexamined Patent Publication 2002-289358 proposes a technology where interference between light that has been emitted from a luminous layer in the direction toward an electrode having translucence and light that has been emitted in the direction toward an electrode having reflecting properties is used to increase the luminous efficiency by setting the distance between the light-emitting position and the reflective layer to such a distance that emitted light has such a wavelength as to resonate.

In Japanese Unexamined Patent Publication 2000-243573, reflection from the interface between an electrode having translucence and a substrate is also taken into consideration, and the distance between the light-emitting position and an electrode having reflecting properties, and the distance between the light-emitting position and the interface between the electrode having translucence and the substrate are both defined.

In the pamphlet of International PCT Patent Publication WO01/039554, interference caused by multiple reflection of light between an electrode having translucency and an electrode having reflecting properties is used to increase the luminous efficiency, by setting the film thickness between the electrode having translucence and the electrode having reflecting properties to such a thickness that light having a desired wavelength resonates.

In all of the above described prior art technologies, interference of emitted light is used to increase the luminous efficiency.

Meanwhile, there is a problem with light that has been emitted from an organic EL device, such that the color tone varies depending on the view angle. Conventionally, the use interference of emitted light in order to reduce such change in the color tone depending on the view angle has not been considered.

In addition, interference as that described above occurs inside organic EL devices having a white luminous layer, and therefore, it is preferable for the light-emitting position to be in proximity to the reflective layer, preferably a distance of no greater than 80 nm, in order for white light having components of a wide range of wavelengths to be emitted efficiently. However, when the light-emitting position is at a distance from the reflective layer, making the distance between the two greater, it becomes difficult for white light having a wide range of spectra to be emitted by means of interference.

Japanese Unexamined Patent Publication 2004-79421 discloses that the distance between the light-emitting position and a reflective layer, and the distance between the light-emitting position and the interface between an electrode having translucence and an external layer are defined, and thereby, an efficient device having excellent white chromaticity can be gained.

### SUMMARY OF THE INVENTION

A first object of the present invention is to provide an organic EL device which can reduce the change in the color tone depending on the view angle.

A second object of the present invention is to provide an organic EL device which can gain excellent white chromaticity.

The present invention provides an organic electroluminescent device comprising: a luminous layer provided between a first electrode and a second electrode; and a reflective layer provided on the first electrode side for reflecting light emitted from the luminous layer and emitting the light from said second electrode side; wherein an optical distance L₁ between a light-emitting position of the luminous layer and the reflective layer is determined so as to allow the light with wavelength λ, which is center wavelength of the emitted light to be taken out, to increase in intensity as a result of interference, and wherein an optical distance L₂ between a reflective interface at the device end portion on the second electrode side and the reflective layer is determined so as to allow the light with wavelength λ to decrease in intensity as a result of interference.

According to the present invention, the optical distance L₁ between the light-emitting position of the luminous layer and the reflective layer is an optical distance for allowing the light having the center wavelength λ to increase in intensity as a result of interference, and the optical distance L₂ between the reflective interface of the device end portion on the second electrode side and the reflective layer is an optical distance for allowing light having the wavelength λ to decrease in intensity as a result of interference. In the following, interference of light caused by the optical distance L₁ is referred to as “first interference,” and interference of light caused by the optical distance L₂ is referred to as “second interference.”

The first interference and the second interference of the present invention are described in reference to FIG. 2.

In the organic EL device shown in FIG. 2, a reflective layer 34 is formed on top of a substrate 37, and a first electrode 31 is provided on top of the reflective layer 34. An organic layer 38 that includes a luminous layer is provided on top of the first electrode 31. In the present embodiment, the luminous layer in the organic layer 38 is formed by making a host material contain a dopant material. The position of light emission 33a in the organic layer 38 generally differs depending on the carrier transportability of the host material in the luminous layer. According to the present invention, in the case where the host material of the luminous layer has electron transportability, the interface between the luminous layer and the hole transport layer becomes the light-emitting position 33a. In addition, in the case where the host material of the luminous layer has hole transportability, the interface between the electron transport layer and the luminous layer becomes the light-emitting position 33a. In the case where the luminous layer has both properties of electron transportability and hole transportability, so-called bipolar transportability, the center area in the direction of the thickness of the luminous layer becomes the light-emitting position 33a.

A second electrode 32 is provided on top of the organic layer 38. In the present embodiment, the second electrode 32 is the top layer of the device, and there is a layer of air above the second electrode 32.

L₁ is the optical distance between the light-emitting position 33a and the reflective layer 34, and L₂ is the optical distance between the upper end portion 32a of the second electrode 32 and the reflective layer 34. The outside of the second electrode 32 is a layer of air, and reflection occurs from the interface between the second electrode 32 and the layer of air, due to the difference in the index of refraction between the second electrode 32 and the layer of air. Accordingly, the upper end portion 32a of the second electrode 32 becomes the reflective interface of the device end portion.

The first interference 40 occurs as interference between light 41 that is emitted from the light-emitting position 33a toward the second electrode 32 side, and light 42 which is emitted from the light-emitting position 33a toward the first electrode 31 side, and is reflected from the reflective layer 34 so as to be emitted to the second electrode 32 side.

The second interference 50 is interference which occurs as a result of multiple reflection of light 51 that has been emitted from the light-emitting position 33a, which is reflection of light from the interface 32a between the second electrode 32 and the layer of air and reflection of light from the reflective layer 34.

The first interference 40 depends on the optical distance L₁ between the light-emitting position 33a and the reflective layer 34. In addition, the second interference 50 depends on the optical distance L₂ between the reflective interface 32a of the device end portion and the reflective layer 34.

The efficiency of light emission from the device is influenced both by the above described first interference 40 and the second interference 50.

Here, in order to describe the change in the color tone depending on the view angle, which has conventionally been a problem, the first interference and the second interference are examined, taking the view angle into consideration. FIG. 3 is a diagram showing a view angle θ. As shown in FIG. 3, in the case where the view angle is θ, the conditions for resonance between the first interference and the second interference can be represented by the following formulas (6) and (7).
2 L₁ cos θ−λ φ₁/2π=m λ (6)
2 L₂ cos θ−λ(φ₁+φ₂)/2π=m λ (7)

Here, m is a natural number, including 0, L₁ is the optical distance between the light-emitting position and the reflective layer, L₂ is the optical distance between the reflective interface of the device end portion and the reflective layer, λ is a resonant wavelength, φ₁ is the phase shift when light is reflected from the reflective layer, and φ₂ is the phase shift when light is reflected from the reflective interface of the device end portion.

As is clear from the above described formulas (6) and (7), the resonant wavelength between the first interference and the second interference shifts to the shorter wavelength side as the view angle θ increases. The taking-out efficiency is the sum of both effects; the first interference and the second interference, and this also shifts to the shorter wavelength side when the view angel increases.

FIG. 4 is a graph illustrating a state where the wavelengths of light that is emitted from the device have shifted to the shorter wavelength side as the view angle increases. It can be seen in the spectrum A having a small half value width, as shown in FIG. 4, that change in the color tone and brightness is greater when the view angle increases and the wavelengths shift to the shorter wavelength side. In contrast it can be seen in the spectrum B having a large half value width that change in the color tone and brightness is small even when the view angle increases and the wavelengths shift to the shorter wavelength side. The present invention provides a spectrum where the taking-out efficiency where the half value width is large in manner described above, and the peak of the spectrum is flat, and thereby, change in the color tone and brightness due to change in the view angle becomes small. In the following, how the present invention can provide taking-out efficiency where the half value width is large and the peak is flat in the manner described above is described.

In the present invention, L₁ is an optical distance for allowing light having the wavelength λ to increase in intensity by means of interference. Accordingly, the first interference is interference for making light having the wavelength λ resonate. Meanwhile, L₂ is an optical distance for allowing light having the wavelength λ to decrease in intensity by means of interference. Therefore, the second interference makes light having the wavelength λ non-resonant, and is interference having respective resonant wavelengths on the shorter wavelength side and on the longer wavelength side of λ. The actual taking-out efficiency is affected both by the first interference and the second interference, and therefore, when these are added, the taking-out efficiency forms a flat spectrum having a large half value width. Accordingly, the present invention provides a flat spectrum for the taking-out efficiency having a large half value width, for example, the spectrum B shown in FIG. 4. Accordingly, as described above, change in the color tone and brightness depending on the view angle can be reduced.

According to the present invention, in the case where the luminous layer is a monochrome luminous layer, it is preferable for the optical distances L₁ and L₂ to satisfy the following formulas (1) to (5).
2 L₁−λ₁ φ₁/2π=mλ₁ (1)
2 L₂−λ₂(φ₁+φ₂)/2π=(n+½)λ₂ (2)
λ_{f}−30<λ<λ_{f}+80 (3)
λ−15<λ₁<λ+15 (4)
λ−15<λ₂<λ+15 (5)

(unit for λ: nm)

Here, m and n are natural numbers, L₁ is the optical distance between the light-emitting position and the reflective layer, L₂ is the optical distance between the reflective interface of the device end portion and the reflective layer, λ_{f} is the fluorescence peak wavelength of the luminous layer, φ₁ is the phase shift when light is reflected from the reflective layer, and φ₂ is the phase shift when light is reflected from the reflective interface of the device end portion.

φ₁ can be represented by the following formula when the index of refraction of the first electrode is nₑ, the index of refraction of the reflective layer is nₘ, and the extinction coefficient of the reflective layer is kₘ.
φ₁=tan⁻¹{2nₑkₘ/(nₑ²−nₘ²−kₘ²)}

Here, when 2nₑkₘ/(nₑ²−nₘ²−kₘ²)>0, 0<φ₁<π/2, and when 2nₑkₘ/(nₑ²−nₘ²−kₘ²)<0, π/2<φ₁<π.

In addition, φ₂ is 0 when the index of refraction of the second electrode is greater than that of the layer outside of the device, and is π when the index of refraction of the second electrode is smaller than that of the layer outside of the device.

In the above described formula (3), the lower limit value of λ is λ_{f}−30, and the upper limit value of λ is λ_{f}+80, where the upper limit value is wider because the fact that the spectrum of taking-out efficiency shifts to the shorter wavelength side when the view angle increases is taken into consideration.

In the present invention, “monochrome” means a color other than white, and colors such as blue, green, red and orange can be cited as examples.

According to the present invention, in the case where the luminous layer is a white light-emitting layer, it is preferable for the optical distances L₁ and L₂ to satisfy the following formulas (1) to (5).
2 L₁−λ₁ φ₁/2π=mλ₁ (1)
2 L₂−λ₂(φ₁+φ₂)/2π=(n+½)λ₂ (2)
λ_{f}−30<λ<λ_{f}+80 (3)
λ−15<λ₁<λ+15 (4)
λ−15<λ₂<λ+15 (5)
λ_{f}−30<λ<λ_{f}+80 (3)
λ−15<λ₁<λ+15 (4)
λ−15<λ₂<λ+15 (5)

(unit for λ: nm)

Here, m and n are natural numbers, L₁ is the optical distance between the light-emitting position and the reflective layer, L₂ is the optical distance between the reflective interface of the device end portion and the reflective layer, λ is the center wavelength in the range of wavelengths of white light for emission, φ₁ is the phase shift when light is reflected from the reflective layer, and φ₂ is the phase shift when light is reflected from the reflective interface of the device end portion.

φ₁ can be represented by the following formula when the index of refraction of the first electrode is nₑ, the index of refraction of the reflective layer is nₘ, and the extinction coefficient of the reflective layer is kₘ.
φ₁=tan⁻¹{2nₑkₘ/(nₑ²−nₘ²−kₘ²)}

Here, when 2nₑkₘ/(nₑ²−nₘ²−kₘ²)>0, 0<φ₁<π/2, and when 2nₑkₘ/(nₑ²−nₘ²−kₘ²)<0, π/2<φ₁<π.

In addition, φ₂ is 0 when the index of refraction of the second electrode is greater than that of the layer outside of the device, and is π when the index of refraction of the second electrode is smaller than that of the layer outside of the device.

In general, the second electrode is an electrode having translucence, and therefore, is formed of a thin layer of a conductive metal oxide or a metal thin film. Accordingly, in the case where the outside of the second electrode is a layer of air, a layer of resin or a layer of glass, the interface between the second electrode and this external layer becomes a reflective interface. On the other hand, in the case where an inorganic protective layer or the like is provided outside of the second electrode, the difference in the index of refraction between the second electrode and the inorganic protective layer is small, and therefore, in some cases, the outside of the second electrode does not become a reflective interface. In such a case, the outside of the inorganic protective layer becomes the reflective interface.

According to the present invention, as described above, the light-emitting position from the luminous layer is the interface between the luminous layer and the layer that is adjacent to the luminous layer on the first electrode side (for example, the hole transport layer) in the case where the host material of the luminous layer has electron transportability, and is the interface between the luminous layer and the layer that is adjacent to the luminous layer on the second electrode side (for example, the electron transport layer) in the case where the host material of the luminous layer has hole transportability.

According to the present invention, it is preferable for the thickness of the metal layer to be no greater than 5 nm in the case where a metal layer is provided between the organic layer that includes the luminous layer and the second electrode. The thickness of the metal layer is made to be no greater than 5 nm, and thereby, the effects of the reflection of light from this metal layer on the first interference and the second interference can be reduced.

According to the present invention, it is preferable for the luminous layer to be formed of a host material and a dopant material. As the host material of the luminous layer, anthracene derivatives, aluminum complexes, rubrene derivatives, aryl amine derivatives and the like can be cited. According to the present invention, the luminous layer may be formed of two layers, where, for example, a blue light-emitting layer and an orange light-emitting layer are laminated, or may be formed of only one layer in the case where the luminous layer is a white light-emitting layer.

As for the dopant material, a singlet luminous material may be used, or a triplet luminous material may be used. In order to gain high efficiency of light emission, it is preferable to use a triplet luminous material which is a phosphorescent material. As the singlet luminous material, perylene derivatives, coumarin derivatives, anthracene derivatives, tetracene derivatives, stilbene derivatives and the like can be cited. In addition, as the triplet luminous material (phosphorecent material), iridium complexes, platinum complexes and the like can be cited.

According to the present invention, an organic layer other than the luminous layer may be provided. As the organic layer, carrier transport layers, such as hole transport layers and electron transport layers can be cited. As the material having hole transportability that is used for the hole transport layer, aryl amine derivatives and the like can be cited. In addition, as the material having electron transportability that is used for the electron transport layer, perylene derivatives, anthraquinone derivatives, anthracene derivatives, rubrene derivatives and the like can be cited.

According to the present invention, the second electrode is generally formed of an electrode having translucence. As this electrode having translucence, translucent conductive metal oxide, such as ITO (indium tin oxide), IZO (indium zinc oxide) and tin oxide, can be cited.

According to the present invention, the first electrode may be formed of an electrode having translucence, such as a conductive metal oxide, in the same manner as with the second electrode, or may be formed of a metal thin film or the like. In the case where the first electrode is formed of a metal thin film, it may also be used as the reflective layer according to the present invention.

According to the present invention, the reflective layer is not particularly limited, as long as it can reflect light, and is generally formed of a metal thin film. As the metal thin film, Ag, Al, Mo, Cr and the like can be cited. Though the film thickness of the reflective layer is not particularly limited, it is generally preferable for it to be within a range from 100 nm to 300 nm.

An organic electroluminescent display according to the present invention is provided with an organic electroluminescent device having a device structure that is sandwiched between an anode and a cathode, an active matrix driving substrate where active devices for supplying a display signal which corresponds to each display pixel to the organic electroluminescent device, and a translucent sealing substrate that is provided so as to face the active matrix driving substrate, which is a top emission type organic electroluminescent display where the organic electroluminescent device is placed between the active matrix driving substrate and the sealing substrate, and the electrode, which is either the cathode or the anode, and provided on the sealing substrate side is a translucent electrode, characterized in that the organic electroluminescent device is an organic electroluminescent device according to the above described present invention.

A color filter of which the color tone is of the same type as the color of the emitted light may be placed between the sealing substrate and the organic electroluminescent device. A color filter of which the color tone is of the same type as the emitted light is used, and thereby, the change in the color tone depending on the view angle can further be reduced, and furthermore, a luminous display device of which the dependency on the view angle is small can be gained.

The organic electroluminescent display according to the present invention is a top emission type display, and therefore, light that is emitted from the organic electroluminescent device is emitted from the sealing substrate on the side opposite to the side where the active matrix is provided. Generally, an active matrix circuit is formed by laminating a number of layers, and in the case of a bottom emission type, emitted light is attenuated due to the existence of this active matrix circuit, but the organic electroluminescent display according to the present invention is of a top emission type, and therefore, light can be emitted without being influenced by this active matrix circuit. In particular, the organic electroluminescent device according to the present invention has a number of luminous units, and the top emission type has fewer films through which emitted light transmits, in comparison with bottom emission types, and therefore, freedom of design for controlling attenuation of emitted light and narrowing of the view angle of emitted light by means of interference of light is increased.

According to the present invention, the spectrum of the efficiency of light emission from the device can be made to be a flat spectrum having a large half value width. Accordingly, the change in the color tone depending on the view angle and the change in the brightness can be reduced, and thus, a luminous display of which the dependency on the view angle is small can be gained.

In addition, in the case where the luminous layer is a white light-emitting layer, light can be emitted approximately evenly throughout the entirety of the wide range of wavelengths of white. Accordingly, emission of white light having excellent chromaticity can be gained.

### BRIEF DESCRIPTION OF THE DRAWINGS

FIG. 1 is a schematic cross sectional diagram showing an organic EL device according to one embodiment of the present invention;

FIG. 2 is a schematic cross sectional diagram illustrating the first interference and the second interference according to the present invention;

FIG. 3 is a schematic diagram showing the view angle θ;

FIG. 4 is a graph showing the change in spectrum of the taking-out efficiency depending on the view angle;

FIG. 5 is a graph showing the results of simulation of the taking-out efficiency in an organic EL device according to Comparative Example 1;

FIG. 6 is a graph showing the change in spectrum of emitted light depending on the view angle in the organic EL device according to Comparative Example 1;

FIG. 7 is a graph showing the results of simulation of the taking-out efficiency in an organic EL device according to Example 1;

FIG. 8 is a graph showing the change in spectrum of emitted light depending on the view angle in the organic EL device according to Example 1;

FIG. 9 is a graph showing the actual taking-out efficiency in Example 1 and Comparative Example 1;

FIG. 10 is a schematic cross sectional diagram showing an organic EL device according to another embodiment of the present invention;

FIG. 11 is a graph showing the results of simulation of the taking-out efficiency in an organic EL device according to Example 2;

FIG. 12 is a graph showing the results of simulation of the taking-out efficiency in an organic EL device according to Comparative Example 2;

FIG. 13 is a graph showing the change in spectrum of emitted light in the organic EL devices of Example 2 and Comparative Example 2;

FIG. 14 is a graph showing the actual taking-out efficiency in Example 2 and Comparative Example 2;

FIG. 15 is a cross sectional diagram showing a bottom emission type organic EL display using an organic EL device according to an embodiment of the present invention; and

FIG. 16 is a cross sectional diagram showing an organic EL display according to an embodiment of the present invention.

### DESCRIPTION OF PREFERRED EMBODIMENTS

In the following, the embodiments of the present invention are more concretely described, but the present invention is not limited to these embodiments.

### EXAMPLE 1

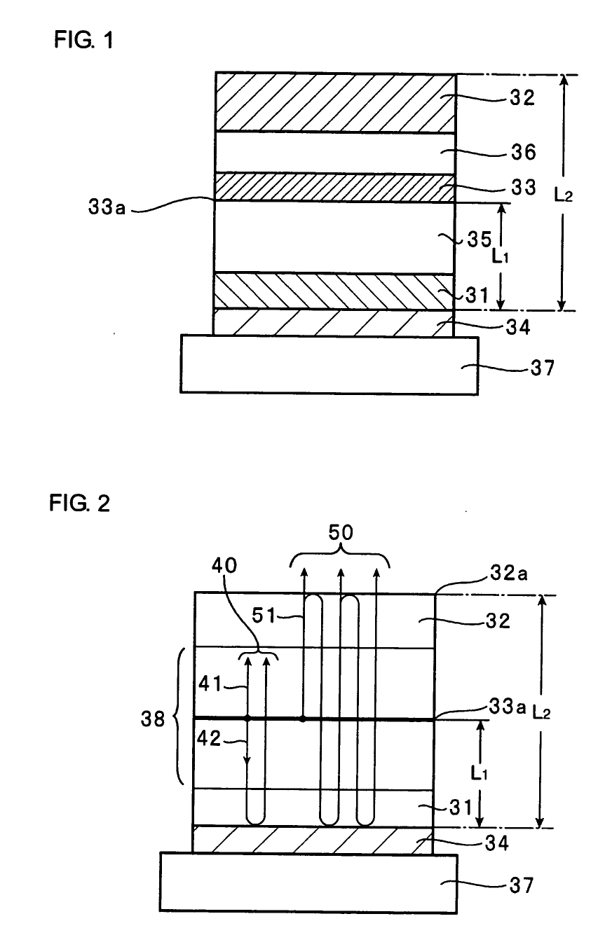

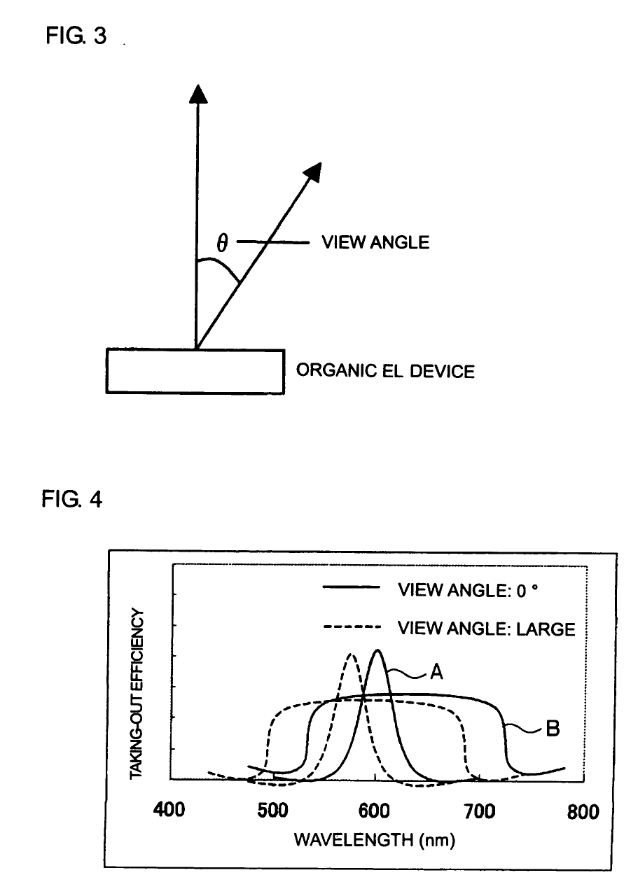

An organic EL device having the device structure shown in FIG. 1 was fabricated. As shown in FIG. 1, a reflective layer 34 (having a film thickness of 100 nm) was formed of Ag on top of a glass substrate 37, a first electrode 31 (having a film thickness of 65 nm) was formed of ITO (indium tin oxide) on top of this, and a hole transport layer 35 (having a film thickness of 120 nm) was formed on top of this.

A green light-emitting layer 33 (having a film thickness of 40 nm) was formed on top of the hole transport layer 35, and an electron transport layer 36 (having a film thickness of 15 nm) was formed on top of this. A second electrode 32 was formed on top of the electron transport layer 36. The second electrode 32 was formed of IZO (indium zinc oxide) (having a film thickness of 140 nm). An Li layer (having a film thickness of 0.3 nm) and an Au layer (having a film thickness of 1.5 nm) were formed as metal layers between the second electrode 32 and the electron transport layer 36. Accordingly, an Li layer/Au layer/IZO layer was formed on top of the electron transport layer 36.

The green light-emitting layer was formed using TBADN as the host material, and 2 weight % of C545T was made to be contained as the dopant material.

TBADN is 2-tertiary-butyl-9,10-di(2-naphthyl) anthracene, and has the following structure. 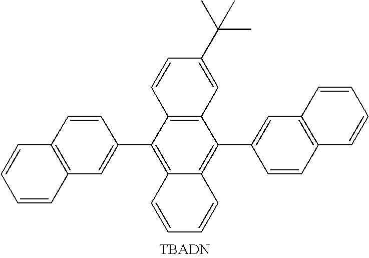
C545T has the following structure.

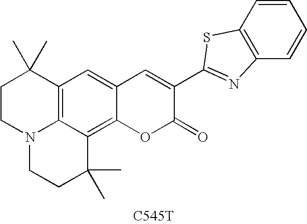

The hole transport layer 5 was formed of NPB. NPB is N, N′-di(naphthacene-1-yl)-N,N′-diphenyl benzidine, and has the following structure.

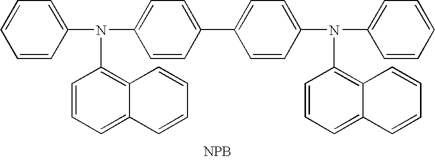

The electron transport layer 6 was formed of BCP. BCP is 2,9-dimethyl-4,7-diphenyl-1,10-phenanthroline, and has the following structure.

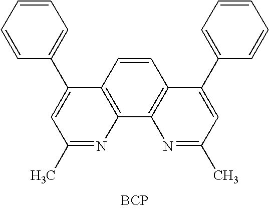

### Comparative Example 1

An organic EL device according to Comparative Example 1 was fabricated in the same manner as in the above described Example 1, except that the film thickness of IZO was changed from 140 nm in the above described Example 1 to 70 nm.

[Calculation of Resonant Wavelengths λ₁ and λ₂]

The resonant wavelength λ₁ resulting from the first interference in Example 1 and Comparative Example 1, and resonant wavelength λ₂ resulting from the second interference were calculated using the formulas (1) and (2). The results of calculation are shown in Table 1. Here, the optical constants, such as the index of refraction n and the extinction coefficient k, are dependent on the wavelength, and therefore, the optical constants for a wavelength of 520 nm as shown in Table 2, were used for λ₁ and λ₂ of Example 1, the optical constants for a wavelength of 540 nm were used for λ₁ of Comparative Example 1, and the optical constants for a wavelength of 640 nm were used for λ₂ of Comparative Example 1 for calculation. Here, 520 nm, 540 nm and 640 nm were respectively estimated from the approximate values of λ₁ and λ₂, which were separately calculated. More precise calculation can be carried out through simulation using a computer.

The fluorescence peak wavelength λ_{f} of the luminous layer was 500 nm.

TABLE 1

| | λ₁ | λ₂ |
|---|---|---|
| Ex. 1 | 531 nm | 514 nm |
| Comp. | 528 nm | 621 nm |
| Ex. 1 | | |

TABLE 2

| | | | | n(Organic | |
|---|---|---|---|---|---|
| | n(Ag) | k(Ag) | n(ITO) | Layer) | n(IZO) |
| 520 nm | 0.0524 | 3.05 | 2.04 | 1.81 | 2.04 |
| 540 nm | 0.0542 | 3.23 | 2.03 | 1.81 | 2.03 |
| 640 nm | 0.066 | 4.11 | 1.97 | 1.78 | 1.97 |

In Comparative Example 1, the fluorescence peak wavelength λ_{f} of the luminous layer was 500 nm, λ₁ was 528 nm, and λ₂ was 621 nm. As is clear from the above described formulas (3) and (5), λ₂ deviates from the range of the present invention, and it is clear that the organic EL device of Comparative Example 1 is out of the scope of the present invention.

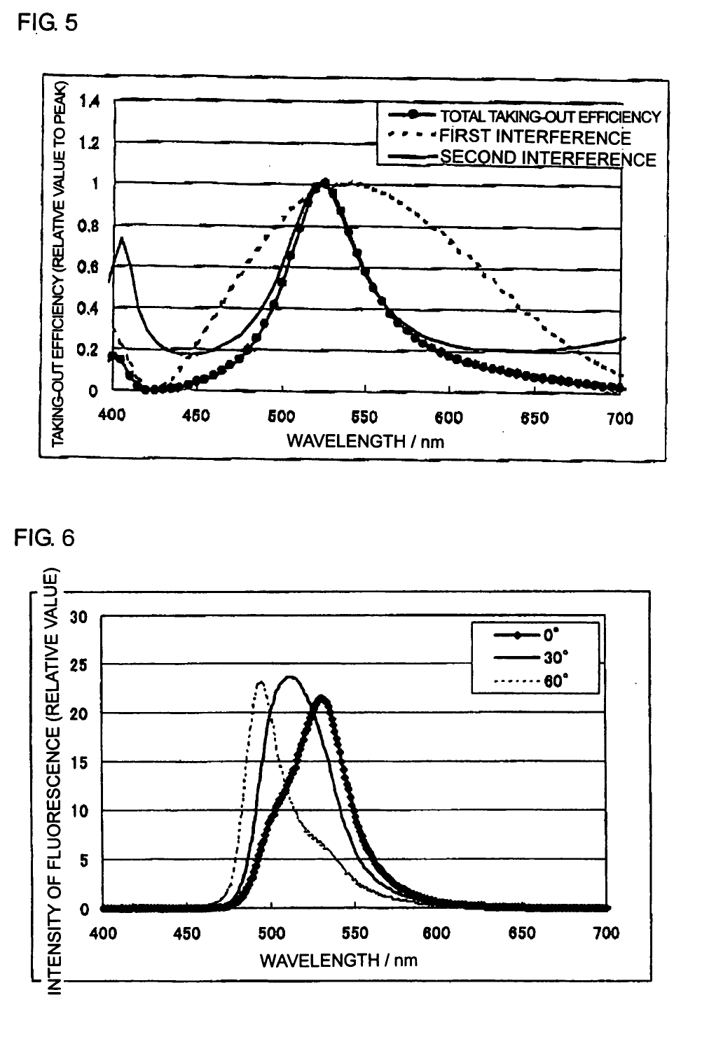

FIG. 5 is a graph showing the results of simulation of the taking-out efficiency in Comparative Example 1. As is clear from FIG. 5, both the first interference and the second interference show a large taking-out efficiency in a green region, and as a result of this, the total taking-out efficiency forms a spectrum of the taking-out efficiency having a maximum in the vicinity of 520 nm, which is green, and a small half value width. As described above, the spectrum of this taking-out efficiency shifts to the shorter wavelength side when the view angle increases. FIG. 6 shows the spectrum of light emitted from this device at view angles of 0°, 30° and 60°. In Comparative Example 1, the half value width of the spectrum of the taking-out efficiency is small, and therefore, as shown in FIG. 6, when the view angle increases, the color of the emitted light greatly changes.

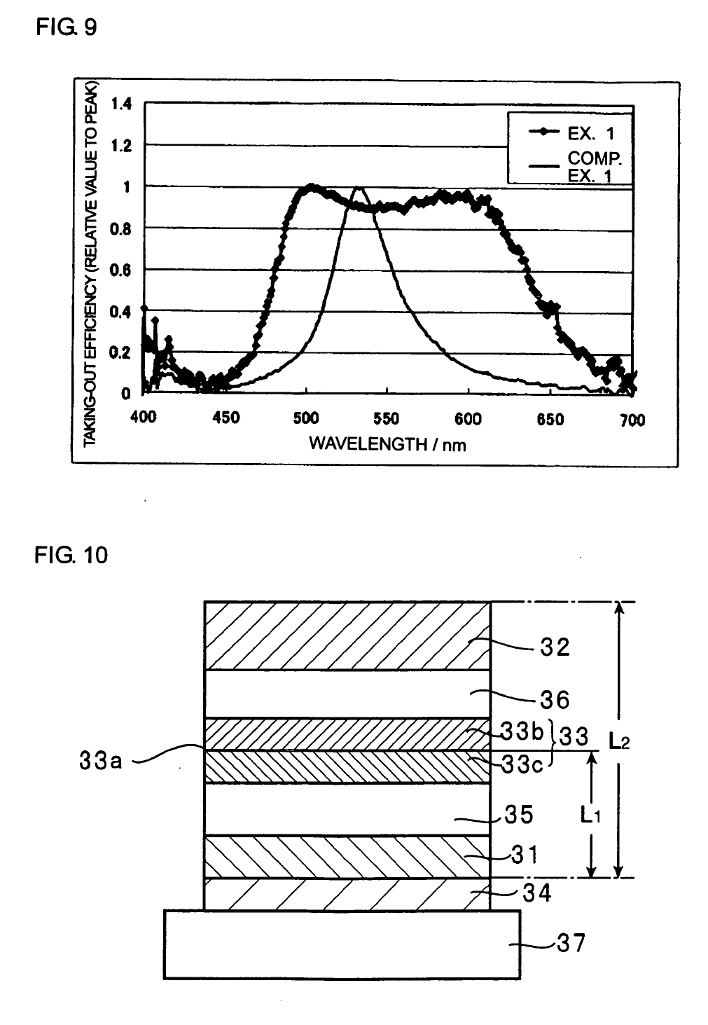

The actual taking-out efficiency is gained by dividing the spectra of FIG. 6 by the spectra of light emitted from the inside of the device, and the results are shown in FIG. 9. Here, as for the spectra of the light emitted from the inside, spectra gained from an organic EL device where the reflective layer did not contain Ag and the structure of remaining portions was the same was used. In the case where there was no reflective layer, the effects of interference were small, and the luminescence can be considered to be approximately equal to the internal luminescence.

It can be seen, as shown in FIG. 6, that the actual taking-out efficiency in the comparative example is approximately equal to the simulation, and has a small half value width.

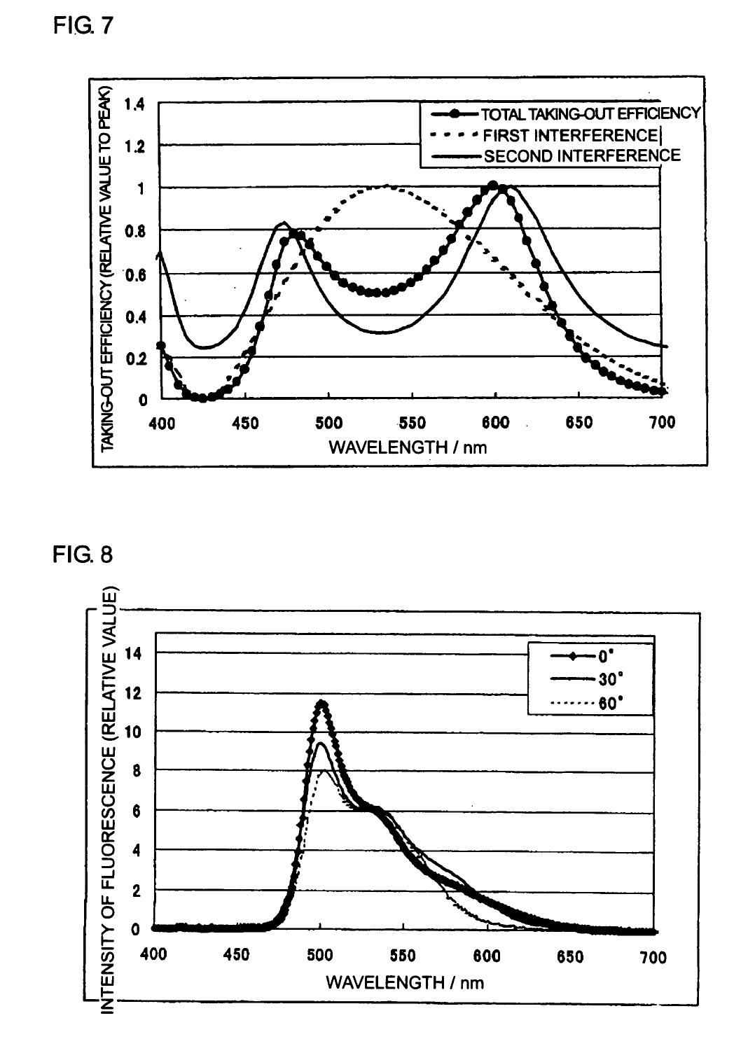

In Example 1, the fluorescence peak wavelength λ_{f} of the luminous layer is 500 nm, λ₁ is 531 nm, and λ₂ is 514 nm, which is within the range of the present invention. FIG. 7 is a graph showing the results of simulation of the taking-out efficiency in this example. As is clear from FIG. 7, in the first interference, the taking-out efficiency in the green region is high, and in the second interference, the taking-out efficiency in blue and red is high. The total taking-out efficiency from this device is influenced by these two interferences, and a high taking-out efficiency can be gained throughout the entirety of a wide wavelength region, as shown in FIG. 7.

FIG. 8 is a graph showing spectra of light emitted from this device at a view angle of 0°, 30° and 60°. It can be seen, as is clear from FIG. 8, that the color of emitted light barely changes depending on the view angle. The actual taking-out efficiency can be gained by dividing the spectrum at the view angle of 0° shown in FIG. 8 by the internal luminescence.

FIG. 9 shows the actual taking-out efficiency in the example. It can be seen, as is clear from FIG. 9, that, the taking-out efficiency from the device of the example is approximately constant throughout a wide range of wavelengths. Table 3 shows the color tone and the change in the brightness (the brightness is 100% when the view angle is 0°) of the organic EL devices of Example 1 and Comparative Example 1 at view angles of 0°, 30° and 60°.

TABLE 3

| | | View Angle | | |
|---|---|---|---|---|
| | | 0° | 30° | 60° |
| Ex. 1 | Chromaticity | (0.256, 0.596) | (0.267, 0.592) | (0.228, 0.628) |
| | (x, y) | | | |
| | Brightness % | 100 | 100 | 85.3 |
| Comp. | Chromaticity | (0.217, 0.696) | (0.161, 0.679) | (0.133, 0.535) |
| Ex. 1 | (x, y) | | | |
| | Brightness % | 100 | 94.5 | 49.2 |

It can be seen, as is clear from the results shown in Table 3, that the change in the color tone and brightness depending on the view angle has been reduced in the organic EL device of Example 1 in comparison with Comparative Example 1.

### EXAMPLE 2

An organic EL device having the device structure shown in FIG. 10 was fabricated. As shown in FIG. 10, a reflective layer 34 (having a film thickness of 100 nm) was formed of Ag on top of a glass substrate 37, a first electrode 31 (having a film thickness of 65 nm) was formed of ITO (indium tin oxide) on top of this, and a hole transport layer 35 (having a film thickness of 100 nm) was formed on top of this.

An orange light-emitting layer 33c (having a film thickness of 15 nm) and a blue light-emitting layer 33b (having a film thickness of 25 nm) were formed in this order on top of the hole transport layer 35. A white light-emitting layer 33 was formed of the blue light-emitting layer 33b and the orange light-emitting layer 33c, and an electron transport layer 36 (having a film thickness of 10 nm) was formed on top of this white light-emitting layer 33. A second electrode 32 was formed on top of the electron transport layer 36. The second electrode 32 was formed of IZO (indium zinc oxide) (having a film thickness of 30 nm). An Li layer (having a film thickness of 0.3 nm) and an Au layer (having a film thickness of 1.5 nm) were formed as metal layers between the second electrode 32 and the electron transport layer 36. Accordingly, an Li layer/Au layer/IZO layer was formed on top of the electron transport layer 36.

In the present example, the white light-emitting layer 33 is formed of a blue light-emitting layer 33b and an orange light-emitting layer 33c, and therefore, the interface between the blue light-emitting layer 33b and the orange light-emitting layer 33c becomes the light-emitting position 33a.

The orange light-emitting layer 33c was formed using NPB as the host material, and 3 weight % of DBZR was made to be contained as a dopant material.

DBzR is 5,12-bis{4-(6-methyl benzothiazole-2-yl) phenyl}-6,11-diphenyl naphthacene, and has the following structure.

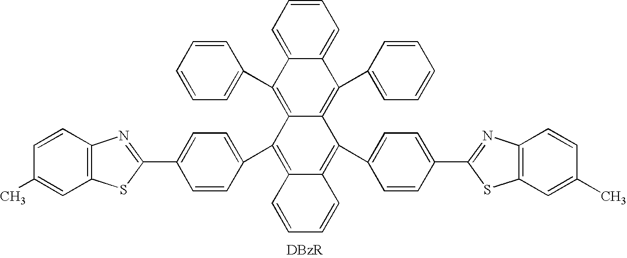

The blue light-emitting layer 33b was formed using TBADN as the host material, and 2 weight % of TBP was made to be contained as a dopant material.

TBP is 2,5,8,11-tetra-tertiary-butyl perylene, and has the following structure.

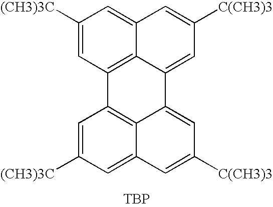

The hole transport layer 35 is formed of NPB.

The electron transport layer 36 is formed of BCP.

### Comparative Example 2

The organic EL device of Comparative Example 2 was fabricated in the same manner as in the above described Example 2, except that the film thickness of the hole transport layer 35 was made to be 45 nm, the film thickness of the orange light-emitting layer 33c was made to be 30 nm, and the film thickness of the blue light-emitting layer was made to be 40 nm in the above described Example 2.

[Calculation of Resonant Wavelengths λ₁ and λ₂]

The resonant wavelength λ₁ resulting from the first interference and the resonant wavelength λ₂ resulting from the second interference in Example 2 and Comparative Example 2 were calculated using the formulas (1) and (2). The results of calculation are shown in Table 4. Here, the optical constants, such as the index of refraction n and the extinction coefficient k, depend on the wavelength, and therefore, the optical constants for a wavelength of 525 nm shown in Table 5 were used for λ₁ and λ₂ of Example 2, the optical constants for a wavelength of 440 nm were used for λ₁ in Comparative Example 2, and the optical constants for a wavelength of 480 nm were used for λ₂ of Comparative Example 2 for calculation. Here, 525 nm, 440 nm and 480 nm were respectively estimated from the values of λ₁ and λ₂, which were separately calculated. More precise calculation can be carried out through simulation using a computer.

TABLE 4

| | λ₁ | λ₂ |
|---|---|---|
| Ex. 2 | 522 nm | 516 nm |
| Comp. | 440 nm | 478 nm |
| Ex. 2 | | |

TABLE 5

| | | | | n(Organic | |
|---|---|---|---|---|---|
| | n(Ag) | k(Ag) | n(ITO) | Layer) | n(IZO) |
| 525 nm | 0.0528 | 3.09 | 2.04 | 1.82 | 2.04 |
| 480 nm | 0.0522 | 2.51 | 2.06 | 1.84 | 2.06 |
| 440 nm | 0.0559 | 2.32 | 2.09 | 1.89 | 2.09 |

In Example 2, when the center wavelength λ of the range wavelengths of white light for emission is 520 nm, λ₁ is 522 nm, and λ₂ is 516 nm, which is within the range of the present invention.

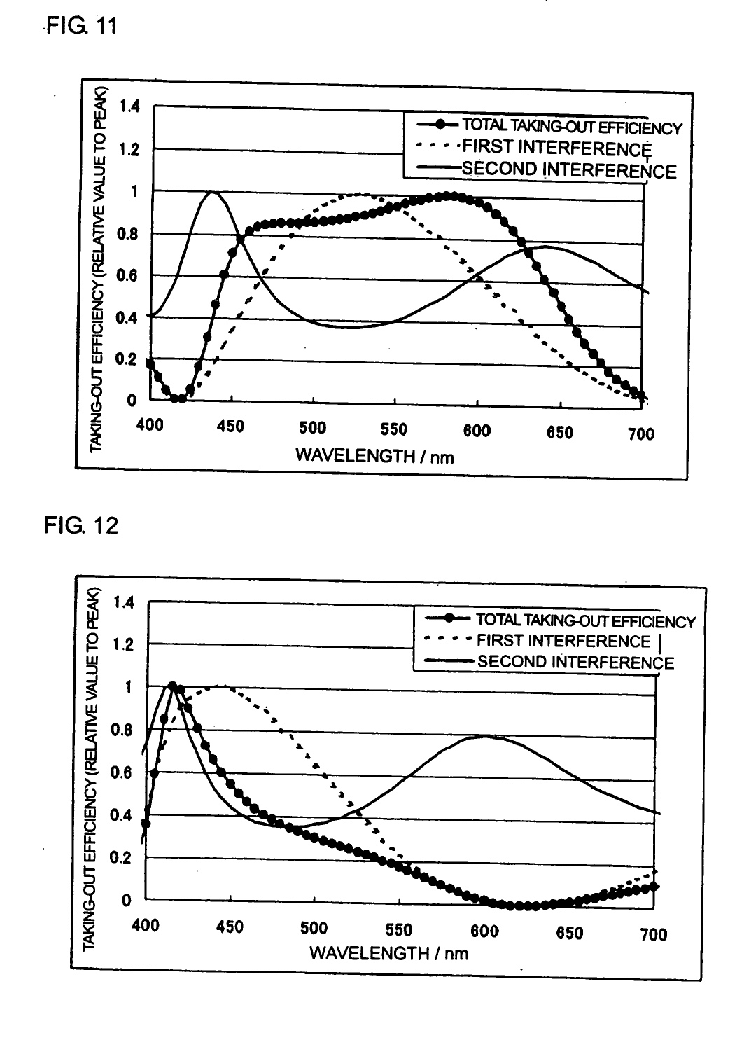

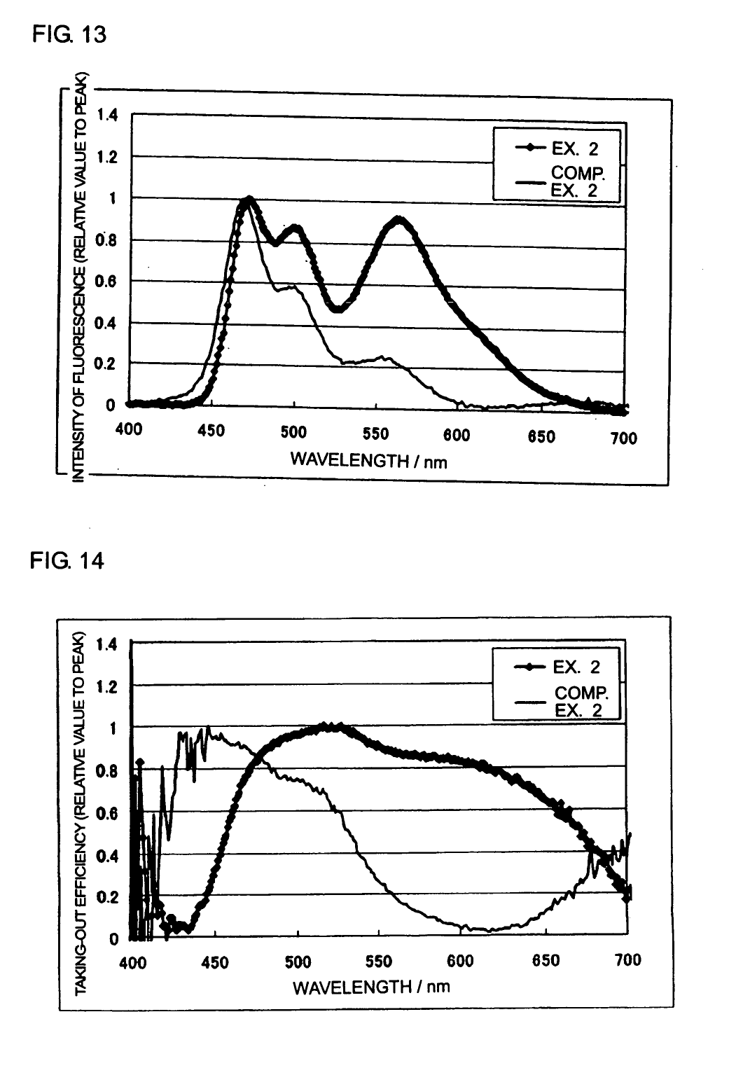

FIG. 11 shows the results of simulation of the taking-out efficiency in a visible light range in Example 2. As shown in FIG. 11, in the first interference, the taking-out efficiency in the green range in the vicinity of 520 nm is high, and in the second interference, the taking-out efficiency in blue and red is high. The total taking-out efficiency from this device is influenced by both of these two interferences, and as a result, is an taking-out efficiency which is approximately even throughout a wide visible light range. Accordingly, as shown in FIG. 13, white light is emitted from the device of Example 2, and the chromaticity was (0.32, 0.42). The division of the spectra, shown in FIG. 13, by the spectra of light emitted from the inside of the device becomes the actual taking-out efficiency. FIG. 14 shows the actual taking-out efficiency in Example 2. Here, as for the spectra of the internal luminescence, spectra that were gained from a device where the reflective layer does not contain Ag and the structure of other portions is the same were used. In the case where there is no reflective layer, the effects of interference are small, and the luminescence can be considered to be approximately equal to the internal luminescence. As shown in FIG. 14, the effects of emission having a large width were gained in the actual experiment, in the same manner as in the simulation of FIG. 11.

In Comparative Example 2, when the center wavelength λ of the range of wavelengths of white light for emission is 520 nm, λ₁ is 440 nm and λ₂ is 478 nm. As is clear from the formula (4) and the formula (5), λ₁ and λ₂ are out of the range of the present invention, and therefore, it is clear that the organic EL device of Comparative Example 2 is out of the scope of the present invention.

FIG. 12 is a graph showing the results of simulation of the taking-out efficiency in Comparative Example 2. As is clear from FIG. 12, the total taking-out efficiency becomes higher in the short wavelength region. Accordingly, as shown in FIG. 13, light having an intense blue component was emitted from this device of Comparative Example 2, and white light having good chromaticity was not gained. Here, the chromaticity was (0.18, 0.28).

FIG. 14 shows the taking-out efficiency that was gained from the experiment of the device of Comparative Example 2. As is clear from FIG. 14, Comparative Example 2 also provides spectra where the taking-out efficiency in the short wavelength region is high, in the same manner as the results of simulation shown in FIG. 12.

As described above, it can be seen that white light having good chromaticity can be gained according to the invention.

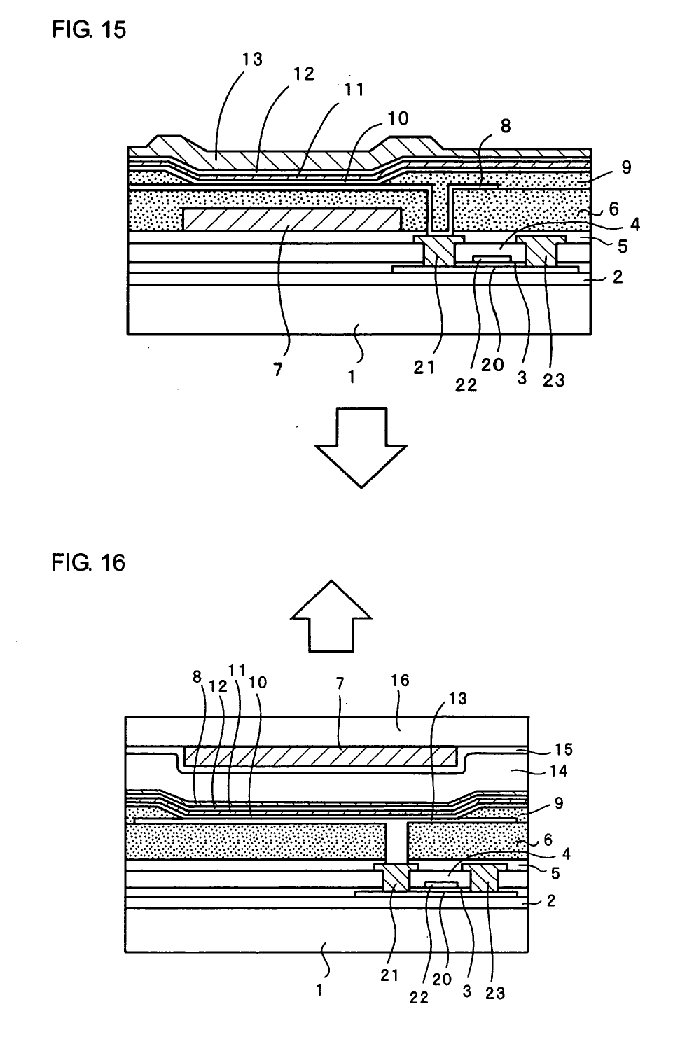

FIG. 15 is a cross sectional diagram showing an organic EL display that is provided with the organic EL device according to an embodiment of the present invention. In this organic EL display, light emission in each pixel is driven using a TFT as an active device. Here, a diode or the like can also be used as an active device. In addition, a color filter is provided to this organic EL device. This organic EL display is a bottom emission type display which emits light to the underside of a substrate 1 for display, as shown by the arrow.

In reference to FIG. 15, a first insulating layer 2 is provided on top of the substrate 1 that is made of a translucent substrate, such as glass. The first insulating layer 2 is formed of, for example, SiO₂ and SiNₓ. A channel region 20 is formed of a polysilicon layer on top of the first insulating layer 2. A drain electrode 21 and a source electrode 23 are formed on top of the channel region 20, and in addition, a gate electrode 22 is provided between the drain electrode 21 and the source electrode 23 via a second insulating layer 3. A fourth insulating layer 4 is provided on top of the gate electrode 22. The second insulating layer 3 is formed of, for example, SiNₓ and SiO₂, and the third insulating layer 4 is formed of SiO₂ and SiNₓ.

A fourth insulating layer 5 is formed on top of the third insulating layer 4. The fourth insulating layer 5 is formed of, for example, SiNₓ. A color filter layer 7 is provided in the portion of a pixel region on top of the fourth insulating layer 5. A first flattened film 6 is provided on top of the color filter layer 7. A through hole is formed in the first flattened film 6 above the drain electrode 21, and a hole injection electrode 8 which is formed of ITO (indium-tin oxide) on top of the first flattened film 6 is introduced into the through hole. A hole injection layer 10 is formed on top of the hole injection electrode (anode) 8 in the pixel region. A second flattened film 9 is formed in portions other than the pixel region.

A monochrome light-emitting device layer 11 according to the present invention is provided on top of the hole injection layer 10. An electron transport layer 12 is provided on top of the light-emitting device layer 11, and an electron injection electrode (cathode) 13 is provided on top of the electron transport layer 12.

As described above, the organic EL device of the present embodiment is formed in such a manner that a hole injection electrode (anode) 8, a hole injection layer 10, a light-emitting device layer 11 having the structure according to the present invention, an electron transport layer 12 and an electron injection electrode (cathode) 13 are laminated on top of a pixel region.

Light of a predetermined color is emitted from the light-emitting device layer 11. This light is emitted to the outside through the substrate 1. On the side of light emission, a color filter layer 7 is provided. In the case where the light-emitting device layer 11 emits monochrome light, a color filter layer 7 of which the color tone is of the same type as the color of light emitted from the light-emitting device layer 11 is provided as the color filter layer 7, and thereby, the color of the emitted light can be adjusted by means of the color filter layer 7, and thus, the change in the color tone depending on the view angle can further be reduced, by providing the color filter layer 7, because the color provided by the color filter layer 7 does not depend on the view angle. In the case where the light-emitting device layer 11 emits white light, a color filter such as R (red), G (green) or B (blue) is provided as the color filter layer 7.

FIG. 16 is a cross sectional diagram showing an organic EL display according to another embodiment of the present invention. The organic EL display of the present embodiment is a top emission type organic EL display which emits light upward from a substrate 1 for display, as illustrated by the arrow.

The portions from the substrate 1 to the anode 8 are fabricated in approximately the same manner as in the embodiment shown in FIG. 15. Here, the color filter layer 7 is not provided on top of the fourth insulating layer 5, but rather, is placed above the organic EL device. Concretely, a color filter layer 7 is attached to a translucent sealing substrate 10 made of glass or the like, and an over-coating layer 15 is coated on top of this, and this is pasted to the top of the anode 8 via a translucent adhesive layer 14, and thereby, the color filter layer 7 is attached. In addition, in the present embodiment, the position of the anode and the cathode is switched from that in the embodiment shown in FIG. 15.

As the anode 8, a transparent electrode is formed by, for example, laminating ITO of which the film thickness is approximately 100 nm and silver of which the film thickness is approximately 20 nm. As for the cathode 13, a reflective electrode is formed as, for example, a thin film of aluminum, chrome or silver having a film thickness of approximately 100 nm. The over-coating layer 15 is formed of an acryl resin or the like so as to have thickness of approximately 1 μm. The color filter layer 7 may be of a pigment type, or may be of a dye type. The thickness thereof is approximately 1 μm.

Light of a predetermined color that has been emitted from the light-emitting device layer 11 is emitted to the outside through the sealing substrate 16. On the emission side, a color filter layer 7 is provided, and as described above, the change in the color tone depending on the view angle can further be reduced. The organic EL display of the present embodiment is of the top emission type, and therefore, the regions where thin film transistors are provided can be used as pixel regions, and thus, the color filter layer 7 is provided in a range that is wider than that of the embodiment shown in FIG. 15. The light-emitting device layer 11 is formed of an organic EL device according to the present invention, and is a light-emitting device layer having high efficiency of light emission, and a wider region can be used as a pixel region according to the present embodiment, and therefore, advantages of the light-emitting device layer having high efficiency of light emission can sufficiently be exploited. In addition, the formation of the light-emitting device layer having a number of luminous units can be carried out without taking the influence of the active matrix into consideration, and therefore, freedom of design can be increased.

Though a glass plate is used as a sealing substrate in the above described embodiment, the sealing substrate is not limited to a glass plate according to the present invention, but rather, films, for example, oxide films, such as SiO₂, and nitride films, such as SiNₓ, can also be used as the sealing substrate. In this case, a sealing substrate in film form can be formed directly on the device, and therefore, it becomes unnecessary to provide a translucent adhesive layer.

What is claimed is:

1. An electroluminescent device comprising: a luminous layer provided between a first electrode and a second electrode; and a reflective layer provided on the first electrode side for reflecting light emitted from said luminous layer and emitting the light from said second electrode side;
wherein an optical distance L₁ between a light-emitting position of said luminous layer and said reflective layer is determined so as to allow the light with wavelength λ, which is center wavelength of the emitted light to be taken out, to increase in intensity as a result of interference, and wherein an optical distance L₂ between a reflective interface at the device end portion on said second electrode side and the reflective layer is determined so as to allow the light with wavelength λ to decrease in intensity as a result of interference.

2. The organic electroluminescent device according to claim 1, wherein said luminous layer is a monochrome light-emitting layer.

3. The organic electroluminescent device according to claim 2, wherein L₁ and L₂ satisfy the following formulas (1) to (5):
2 L₁−λ₁ φ₁/2π=mλ₁ (1)
2 L₂−λ₂(φ₁+φ₂)/2π=(n+½)λ₂ (2)
λ_{f}−30<λ<λ_{f}+80 (3)
λ−15<λ₁<λ+15 (4)
λ−15<λ₂<λ+15 (5)
(unit for A: nm)
where m and n are natural numbers, L₁ is the optical distance between the light-emitting position and the reflective layer, L₂ is the optical distance between the reflective interface at the device end portion and the reflective layer, λ_{f} is the fluorescence peak wavelength of the luminous layer, φ₁ is the phase shift when light is reflected from the reflective layer, and φ₂ is the phase shift when light is reflected from the reflective interface at the device end portion.

4. The organic electroluminescent device according to claim 1, wherein said luminous layer is a white light-emitting layer.

5. The organic electroluminescent device according to claim 4, wherein L₁ and L₂ satisfy the following formulas (1) to (5):
2 L₁−λ₁ φ₁/2π=mλ₁ (1)
2 L₂−λ₂(φ₁+φ₂)/2π=(n+½)λ₂ (2)
λ_{f}−30<λ<λ_{f}+80 (3)
λ−15<λ₁<λ+15 (4)
λ−15<λ₂<λ+15 (5)
(unit for A: nm)
where m and n are natural numbers, L₁ is the optical distance between the light-emitting position and the reflective layer, L₂ is the optical distance between the reflective interface at the device end portion and the reflective layer, λ is the center wavelength in the range of wavelengths of white light for emission, φ₁ is the phase shift when light is reflected from the reflective layer, and φ₂ is the phase shift when light is reflected from the reflective interface at the device end portion.

6. The organic electroluminescent device according to claim 1, wherein a metal layer of which the thickness is no greater than 5 nm is provided between said luminous layer and said second electrode.

7. The organic electroluminescent device according to claim 1, wherein the outside of the reflective interface at said device end portion is a layer of air, a layer of resin or a layer of glass.

8. An organic electroluminescent display, which is a top emission type organic electroluminescent display, comprising: an organic electroluminescent device having a device structure that is sandwiched between an anode and a cathode; an active matrix driving substrate where active devices for supplying a display signal to each display pixel of said organic electroluminescent device; and a translucent sealing substrate provided so as to face the active matrix driving substrate,
wherein said organic electroluminescent device is placed between said active matrix driving substrate and said sealing substrate, and the electrode provided on the sealing substrate side, which is either said cathode or said anode, is a translucent electrode,
and wherein said organic electroluminescent device is the organic electroluminescent device according to claim 1.

9. The organic electroluminescent display according to claim 8, wherein a color filter is placed between said organic electroluminescent device and said sealing substrate.
